(19) United States
(12) Patent Application Publication
(10) Pub. No.: US 2017/0090232 A1
(43) Pub. Date: Mar. 30, 2017

(54) DISPLAY SUBSTRATE, MANUFACTURING METHOD THEREOF AND DISPLAY DEVICE

(71) Applicants: Boe Technology Group Co., Ltd., Beijing (CN); Hefei Xinsheng Optoelectronics Technology Co., Ltd., Anhui (CN)

(72) Inventors: Wenhao Tang, Beijing (CN); Sangman Yuk, Beijing (CN); Bin Li, Beijing (CN); Huifang Yuan, Beijing (CN); Tao Zhu, Beijing (CN); Haibin Yin, Beijing (CN); Jian Chen, Beijing (CN); Anxin Dong, Beijing (CN); Qun Fang, Beijing (CN); Guoqiang Zhong, Beijing (CN); Xinxin Fu, Beijing (CN)

(21) Appl. No.: 15/140,741

(22) Filed: Apr. 28, 2016

(30) Foreign Application Priority Data
Sep. 28, 2015 (CN) 201510629582.4

(51) Int. Cl. G02F 1/1339; G02F 1/1335; G02F 1/1368; H01L 27/12

(52) U.S. Cl. CPC G02F 1/13394; H01L 27/1288; H01L 27/1222; G02F 1/133512; G02F 1/1368; G02F 2001/13398; G02F 2001/136222

(57) ABSTRACT

Embodiments of the present invention provide a display substrate, a manufacturing method thereof and a display device, simplifying the manufacturing process and reducing the production cost, meanwhile, improving the panel display quality. The method comprises: forming, on a base substrate, a non-transparent material layer for manufacturing a black matrix; forming, on the substrate where the above step is performed, a transparent material layer for manufacturing primary and secondary column shaped spacers; forming a pattern of the primary and secondary column shaped spacers and the black matrix using a composition process.

### RELATED APPLICATIONS

The present application claims the benefit of Chinese Patent Application No. 201510629582.4, filed Sep. 28, 2015, the entire disclosure of which is incorporated herein by reference.

### TECHNICAL FIELD

The present invention relates to the field of display technology, particularly to a display substrate, a manufacturing method thereof and a display device.

### BACKGROUND OF THE INVENTION

The thin film transistor-liquid crystal display (hereinafter referred to as TFT-LCD) has become the mainstream of the panel display by right of its characteristics of low power consumption, relatively low manufacturing cost and free of radiation etc., and has been widely applied in various display elements e.g., displays of electronic devices such as mobile phones, personal digital assistants (PDAs), computers, televisions. The working principle thereof is mainly using electric field to control the arrangement state of the liquid crystal molecules, and determine whether the light generated by the backlight source can pass through the liquid crystal molecules, so as to achieve a display effect of light and shade on the display screen.

The TFT-LCD panel is formed by cell alignment of a color film substrate and an array substrate, these two substrates are isolated with a spacer to form a space for liquid crystal injection, and packaging of the liquid crystals is accomplished by using seal agent at the peripheral part between these two substrates. In order to maintain the cell gap between the color film substrate and the array substrate, at present, a column shaped spacer is generally manufactured on the color film substrate to maintain the cell thickness.

FIG. 1 is a sectional view of a side face of a color film substrate in the prior art, as shown in FIG. 1, the color film substrate comprises a glass substrate 101 and a black matrix (BM) structure 102, pixel resin 103 and a common electrode 104 arranged thereon successively. A column shaped spacer 105 is arranged on the common electrode 104. The manufacturing of the color film substrate of the prior art is as follows: firstly, forming a black matrix structure 102 on a glass substrate 101, then forming pixel resin 103 on the glass substrate 101 and the black matrix structure 102 successively, and then forming a common electrode 104 on the black matrix structure 102 and the pixel resin 103, finally forming a column shaped spacer 105 on the common electrode 104.

From the above it can be seen that two coating processes and manufacturing processes of exposing and developing are required to form the back matrix structure 102 and the column shaped spacer 105 in the prior art. Since the manufacturing process of exposing and developing is relatively complicated, the cost will be increased accordingly. In addition, in order to solve this problem in the prior art, a layer of black matrix material layer is coated on the substrate firstly, the black matrix structure 102 and the column shaped spacer 105 are then formed through a composition process, as shown in FIG. 2; in this process, because the optical density (OD) value of the black matrix material is relatively small, the formed black matrix structure 102 and the column shaped spacer 105 have a relatively large thickness, and have a bad flatness, which may result in bad influence to the subsequent cell alignment process, and finally result in poor panel display.

### SUMMARY OF THE INVENTION

Embodiments of the present invention provide a display substrate, a manufacturing method thereof and a display device, simplifying the manufacturing process and reducing the production cost, meanwhile, improving the panel display quality.

An embodiment of the present invention provides a method of manufacturing a display substrate, the method comprising:

forming, on a base substrate, a non-transparent material layer for manufacturing a black matrix;

forming, on the substrate where the above step is performed, a transparent material layer for manufacturing primary and secondary column shaped spacers; and

forming a pattern of the primary and secondary column shaped spacers and the black matrix using a composition process.

In the method of manufacuring a display substrate provided by the embodiment of the present invention, a non-transparent material layer for manufacturing a black matrix is formed on a base substrate firstly, then a transparent material layer for manufacturing primary and secondary column shaped spacers is formed; finally the black matrix and the primary and secondary column shaped spacers are formed through a composition process. That is, in this embodiment, the manufacuring of the black matrix and the primary and secondary column shaped spacers is accomplished only through two coating processes and one etching process, which simplifies the manufacturing process and reduces the production cost; moreover, since the manufacturing material of the primary and secondary column shaped spacers is a transparent material, the black matrix can be made of a material with a relatively large OD value, thus the problem that the column shaped spacer is too high due to a relatively low OD value thereby influencing the panel display quality can be avoided.

Optionally, a segment difference between the formed primary and secondary column shaped spacers is 0.3˜0.7 μm.

The segment difference between the primary and secondary column shaped spacers formed through this method is 0.3˜0.7 μm. If the segment difference is in this range, it can not only play protection function to the display panel so as to prevent the display panel from being deformed due to extrusion, but also be benefit for improving the panel display quality.

Optionally, forming a pattern of the primary and secondary column shaped spacers and the black matrix using a composition process comprises:

forming a pattern of the primary and secondary column shaped spacers and the black matrix by exposing and developing photoresist using a mask plate corresponding to the pattern of the primary and secondary column shaped spacers.

The pattern of the primary and secondary column shaped spacers and the black matrix can be formed only through one exposing process by exposing and developing photoresist using a mask plate corresponding to the pattern of the primary and secondary column shaped spacers, which is benefit for simplifying the manufacturing process and reducing the production cost.

Optionally, the mask plate comprises a fully transparent area corresponding to the primary column shaped spacer and a semi-transparent area corresponding to the secondary column shaped spacer; or the mask plate comprises a first aperture corresponding to the primary column shaped spacer and a second aperture corresponding to the secondary column shaped spacer; wherein a diameter of the first aperture is greater than a diameter of the second aperture.

The primary and secondary spacers and the black matrix can be formed only by using a mask plate comprising a fully transparent area corresponding to the primary column shaped spacer and a semi-transparent area corresponding to the secondary column shaped spacer, or a mask plate comprising a first aperture and a second aperture corresponding to the primary and secondary spacers respectively and then through an exposing process.

Optionally, forming a pattern of the primary and secondary column shaped spacers and the black matrix using a composition process comprises:

performing exposure using a mask plate comprising a fully transparent area corresponding to a pattern of the primary column shaped spacer and a semi-transparent area corresponding to a pattern of the secondary column shaped spacer so as to cure transparent material and non-transparent material of areas corresponding to the pattern of the primary and secondary column shaped spacers; removing uncured transparent material and non-transparent material using developer, so as to form a pattern of the primary and secondary column shaped spacers and the black matrix; or

performing exposure using a mask plate comprising a first aperture corresponding to a pattern of the primary column shaped spacer and a second aperture corresponding to a pattern of the secondary column shaped spacer so as to cure transparent material and non-transparent material of areas corresponding to the pattern of the primary and secondary column shaped spacers; removing uncured transparent material and non-transparent material using developer, so as to form a pattern of the primary and secondary column shaped spacers and the black matrix.

Optionally, the display substrate further comprises a thin film transistor, a color film layer and a pixel electrode; prior to forming a non-transparent material layer for manufacturing a black matrix, the method further comprises:

forming, on the base substrate, a pattern of the thin film transistor;

forming, on the substrate comprising the pattern of the thin film transistor, a pattern of the color film layer; and

forming, on the substrate comprising the pattern of the color film layer, a pattern of the pixel electrode.

Optionally, prior to forming a pattern of a pixel electrode, the method further comprises:

forming, on the substrate comprising the pattern of the color film layer, a passivation layer for protecting the thin film transistor and the color film layer from being damaged.

Prior to forming the pattern of the pixel electrode, a passivation layer is formed on the substrate comprising the pattern of the color film layer, the passivation layer can protect the color film layer and the thin film transistor from being damaged in the subsequent process effectively.

Optionally, forming a pattern of the primary and secondary column shaped spacers and the black matrix using a composition process comprises:

forming a pattern of the primary and secondary column shaped spacers and the black matrix using a one-time composition process.

The primary and secondary column shaped spacers are both formed above the black matrix using a one-time composition process, which simplifies the manufacturing process and reduces the production cost.

Based on the same inventive concept, an embodiment of the present invention further provides a display substrate manufactured using the above method, the display substrate comprising:

a base substrate;

a black matrix located on the base substrate;

column shaped spacers formed at a side of the black matrix away from the base substrate, the column shaped spacers comprising a primary column shaped spacer and a secondary column shaped spacer.

The display substrate in the embodiment of the present invention comprises a base substrate, a black matrix located on the base substrate; column shaped spacers formed at a side of the black matrix away from the base substrate, the column shaped spacers comprising a transparent primary column shaped spacer and a transparent secondary column shaped spacer. Since the primary and secondary column shaped spacers are formed using a transparent material, the black matrix can be made of a material with a relatively large OD value, thus the problem that the column shaped spacer is too high due to a relatively low OD value thereby influencing the panel display quality can be avoided.

Optionally, a segment difference between the primary and secondary column shaped spacers is 0.3˜0.7 μm.

The segment difference between the primary and secondary column shaped spacers formed through this method is 0.3˜0.7 μm. If the segment difference is in this range, it can not only play protection function to the display panel so as to prevent the display panel from being deformed due to extrusion, but also be benefit for improving the panel display quality.

Optionally, the black matrix is made of a non-transparent material, the primary and secondary column shaped spacers are made of a transparent material.

The black matrix is formed using a non-transparent material, the black matrix formed has the function of preventing light crosstalk, and improving the display quality of the panel. When the primary and secondary column shaped spacers are formed using the transparent material, the black matrix can be made of a material with a relatively large OD value, thus the problem that the column shaped spacer is too high due to a relatively low OD value thereby influencing the panel display quality can be avoided.

Optionally, the display substrate further comprises: a thin film transistor located above the base substrate; a color film layer located above the layer where the thin film transistor locates; a pixel electrode located above the color film layer.

Forming the color film layer on the display panel where the thin film transistor locates using the COA technology can avoid cell alignment error produced in the cell alignment process and is benefit for improving the display quality of the panel.

Optionally, the display substrate further comprises a passivation layer arranged between the color film layer and the pixel electrode, for protecting the thin film transistor and the color film layer from being damaged.

A passivation layer is arranged between the color film layer and the pixel electrode, the passivation layer can protect the color film layer and the thin film transistor from being damaged in the subsequent process effectively.

Based on the same inventive concept, an embodiment of the present invention further provides a display device, the display device comprising the above display substrate.

### BRIEF DESCRIPTION OF THE DRAWINGS

FIG. 1 is a structural schematic diagram of a display substrate in the prior art;

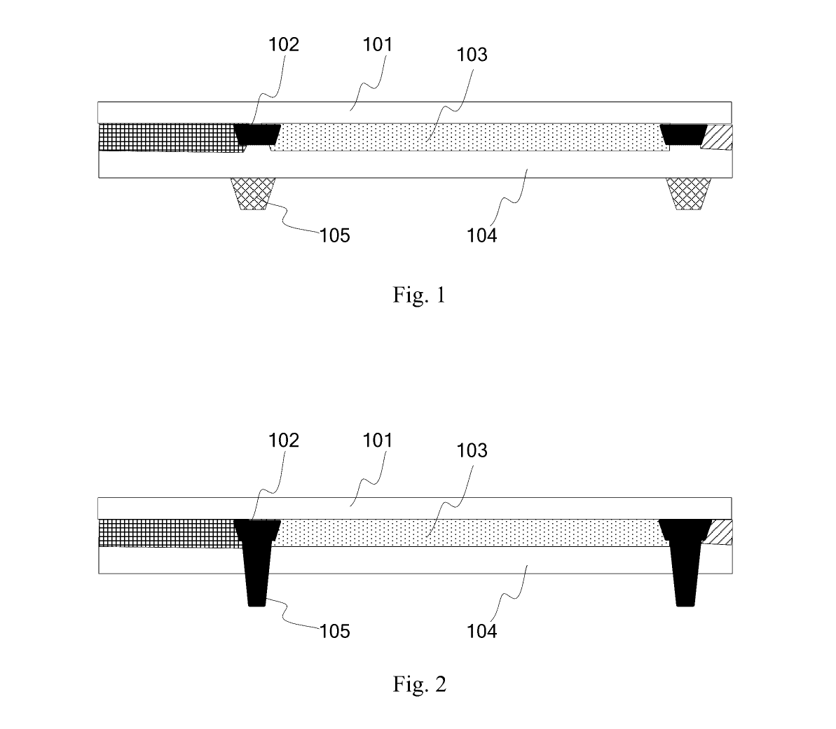

FIG. 2 is a structural schematic diagram of another display substrate in the prior art;

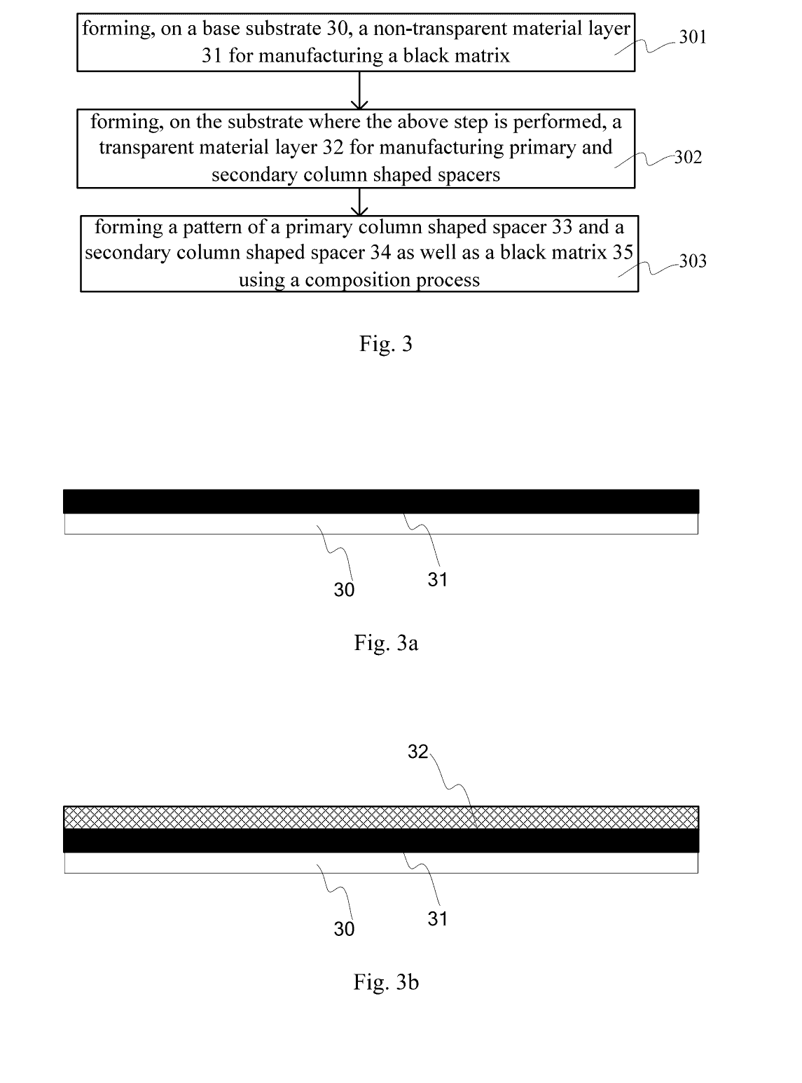

FIG. 3 is a schematic diagram of a method of manufacturing a display substrate provided by an embodiment of the present invention;

FIGS. 3a-3c are schematic diagrams of a manufacturing process for a display substrate provided by an embodiment of the present invention;

FIG. 3d is a flow diagram of exposing and developing when manufacturing a display substrate provided by an embodiment of the present invention;

FIG. 4 is a schematic diagram of another method of manufacturing a display substrate provided by an embodiment of the present invention;

FIGS. 5-12 are schematic diagrams of another manufacturing process for a display substrate provided by an embodiment of the present invention;

FIG. 13 is a structural schematic diagram of a display device provided by an embodiment of the present invention; and

FIG. 14 is a structural schematic diagram of another display device provided by an embodiment of the present invention.

### DETAILED DESCRIPTION OF THE INVENTION

Embodiments of the present invention of the present invention provide a display substrate, a manufacturing method thereof and a display device, simplifying the manufacturing process and reducing the production cost, meanwhile, improving the panel display quality.

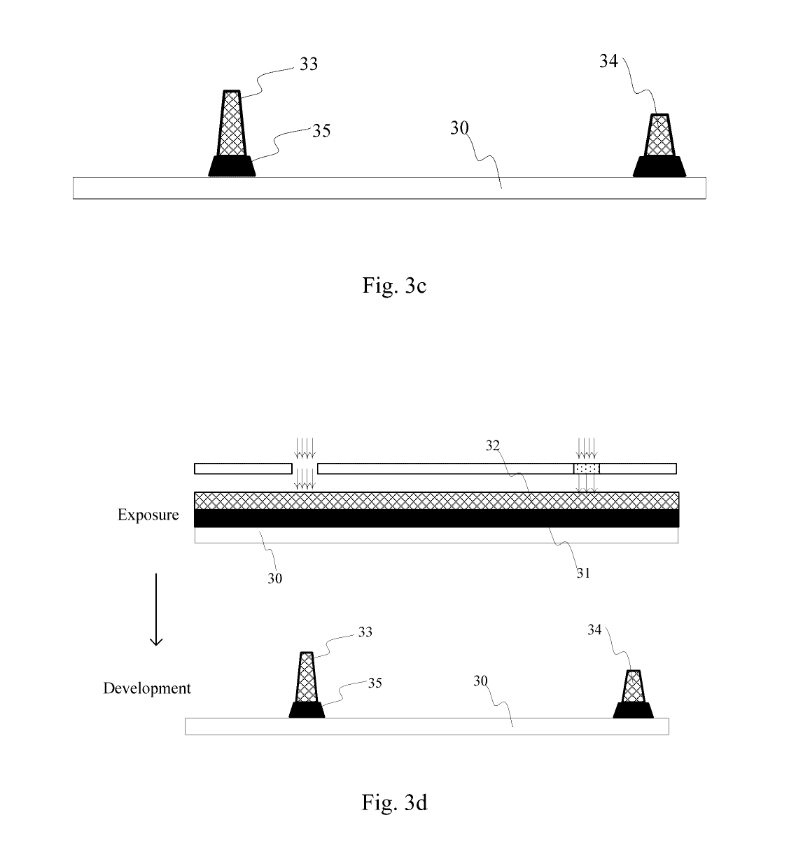

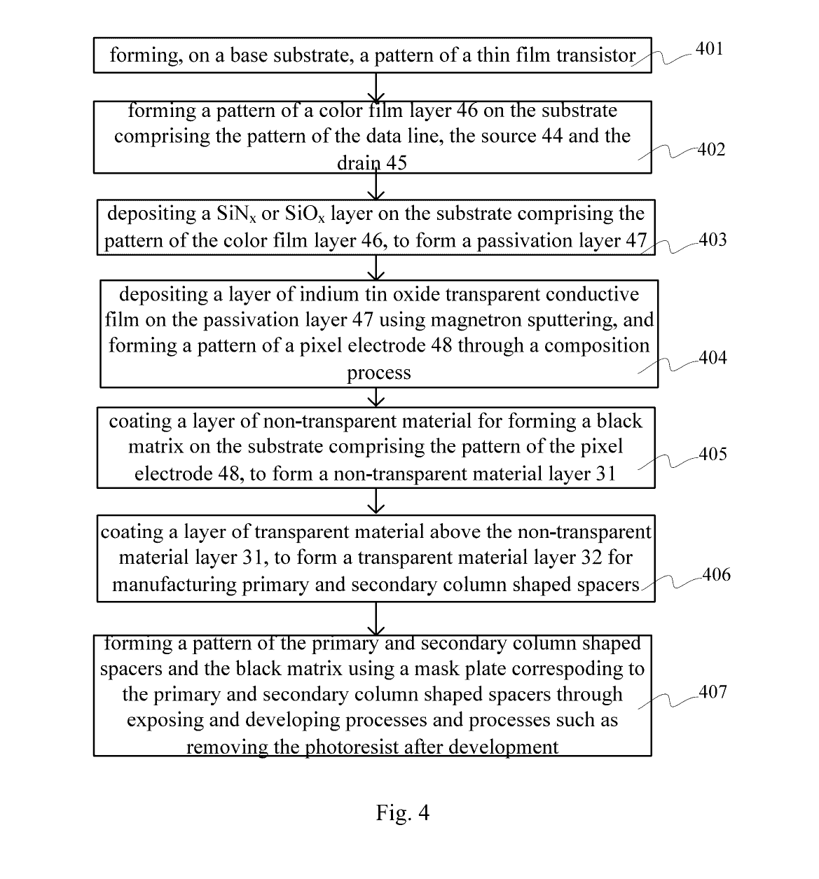

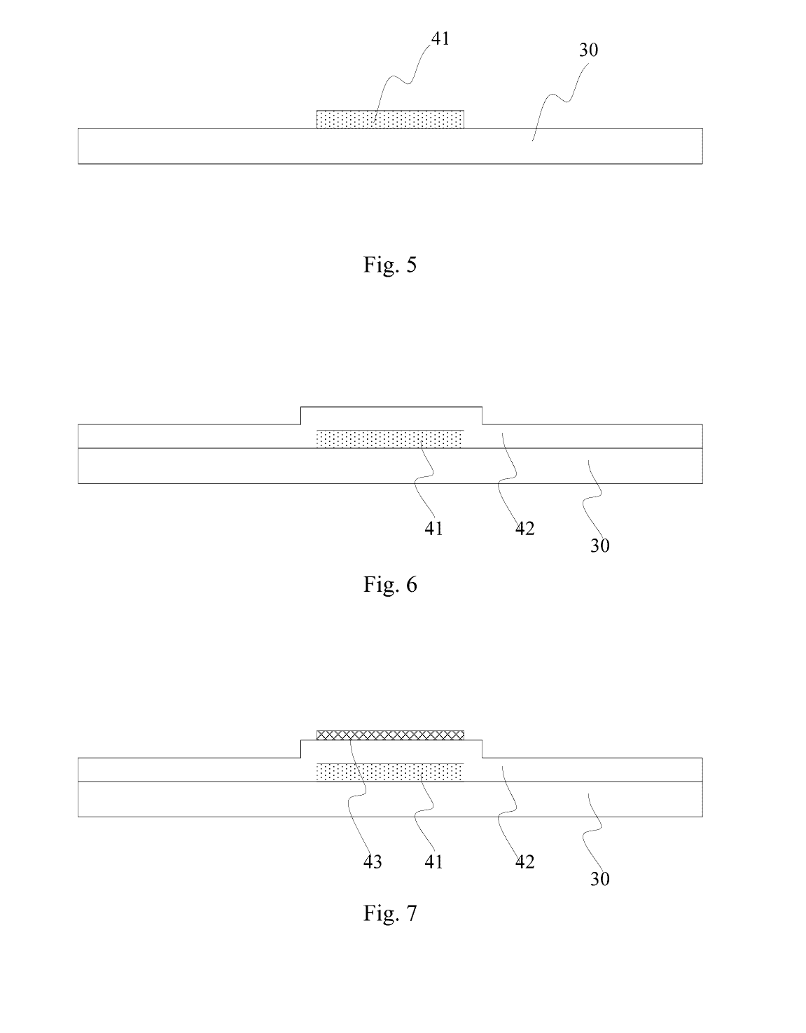

An embodiment of the present invention provides a method of manufacturing a display substrate. Referring to FIG. 3, the method comprises:

Step 301, referring to FIG. 3a, forming, on a base substrate 30, a non-transparent material layer 31 for manufacturing a black matrix;

Step 302, referring to FIG. 3b, forming, on the substrate where the above step is performed, a transparent material layer 32 for manufacturing primary and secondary column shaped spacers;

Step 303, referring to FIG. 3c, forming a pattern of a primary column shaped spacer 33 and a secondary column shaped spacer 34 as well as a black matrix 35 using a composition process.

In the method of manufacturing a display substrate provided by an embodiment of the present invention, a non-transparent material layer for manufacturing a black matrix is formed on a base substrate firstly, then a transparent material layer for manufacturing primary and secondary column shaped spacers is formed; finally the black matrix and the primary and secondary column shaped spacers are formed through a composition process; i.e., in this embodiment, the manufacturing of the black matrix and the primary and secondary column shaped spacers is accomplished only through two coating processes and one etching process, which simplifies the manufacturing process and reduces the production cost; moreover, since the manufacturing material of the primary and secondary column shaped spacers is a transparent material, the black matrix can be made of a material with a relatively large OD value, thus the problem that the column shaped spacer is too high due to a relatively low OD value thereby influencing the panel display quality can be avoided.

Further, a segment difference between the primary column shaped spacer 33 and the secondary column shaped spacer 34 formed is 0.3˜0.7 μm.

The segment difference between the primary and secondary column shaped spacers formed through this method is 0.3˜0.7 μm. If the segment difference is in this range, it can not only play protection function to the display panel so as to prevent the display panel from being deformed due to extrusion, but also be benefit for improving the panel display quality.

In the present invention, the composition process can only comprise a photoetching process, or, comprise a photoetching process and an etching step, meanwhile, it can also comprise other processes such as printing, ink-jetting for forming a predetermined pattern; the photoetching process refers to a process comprising processes of filming, exposing, developing and so on for forming a pattern using photoresist, mask plate, exposure machine etc. Corresponding composition processes can be selected based on the structures formed in the embodiments of the present invention.

At present, a negative photoresist material is generally selected when manufacturing the primary and secondary spacers. Further, forming a pattern of the primary and secondary column shaped spacers and the black matrix using a composition process comprises:

after coating the photoresist, performing a pre-baking process, pre-baking for 100 seconds under a condition of 90° C., so as to enhance the adhesiveness of the photoresist, release the stress within the photoresist film, and prevent the photoresist from breaking off and polluting the device; and

forming the pattern of the primary and secondary column shaped spacers and the black matrix by exposing and developing the photoresist using a mask plate corresponding to the pattern of the primary and secondary column shaped spacers.

The pattern of the primary and secondary column shaped spacers and the black matrix can be formed only through one exposing process by exposing and developing photoresist using a mask plate corresponding to the pattern of the primary and secondary column shaped spacers, which is benefit for simplifying the manufacturing process and reducing the production cost.

Further, the mask plate comprises a fully transparent area corresponding to the primary column shaped spacer and a semi-transparent area corresponding to the secondary column shaped spacer; or

the mask plate comprises a first aperture corresponding to the primary column shaped spacer and a second aperture corresponding to the secondary column shaped spacer; wherein a diameter of the first aperture is greater than a diameter of the second aperture.

The primary and secondary spacers and the black matrix can be formed only by using a mask plate comprising a fully transparent area corresponding to the primary column shaped spacer and a semi-transparent area corresponding to the secondary column shaped spacer, or a mask plate comprising a first aperture and a second aperture corresponding to the primary and secondary spacers respectively and then through an exposing process.

In an actual manufacturing process, referring to FIG. 3d, forming a pattern of the primary and secondary column shaped spacers and the black matrix using a composition process specifically may comprise:

performing exposure using a mask plate comprising a fully transparent area corresponding to a pattern of the primary column shaped spacer and a semi-transparent area corresponding to a pattern of the secondary column shaped spacer so as to cure transparent material and non-transparent material of areas corresponding to the pattern of the primary and secondary column shaped spacers; removing uncured transparent material and non-transparent material using developer, so as to form a pattern of the primary and secondary column shaped spacers and the black matrix; or

performing exposure using a mask plate comprising a first aperture corresponding to a pattern of the primary column shaped spacer and a second aperture corresponding to a pattern of the secondary column shaped spacer so as to cure transparent material and non-transparent material of areas corresponding to the pattern of the primary and secondary column shaped spacers; removing uncured transparent material and non-transparent material using developer, so as to form a pattern of the primary and secondary column shaped spacers and the black matrix.

Further, the display substrate further comprises a thin film transistor, a color film layer and a pixel electrode; prior to forming a layer of non-transparent material layer for manufacturing the black matrix, the method may further comprise:

forming, on the base substrate, a pattern of the thin film transistor;

forming, on the substrate comprising the pattern of the thin film transistor, a pattern of the color film layer; and

forming, on the substrate comprising the pattern of the color film layer, a pattern of the pixel electrode.

Further, prior to forming a pattern of a pixel electrode, the method further comprises:

forming, on the substrate comprising the pattern of the color film layer, a passivation layer for protecting the thin film transistor and the color film layer from being damaged.

Prior to forming the pattern of the pixel electrode, a passivation layer is formed on the substrate comprising the pattern of the color film layer, the passivation layer can protect the color film layer and the thin film transistor from being damaged in the subsequent process effectively.

Further, the method further comprises: forming a pattern of the pixel electrode using a composition process on the substrate where the passivation layer is formed.

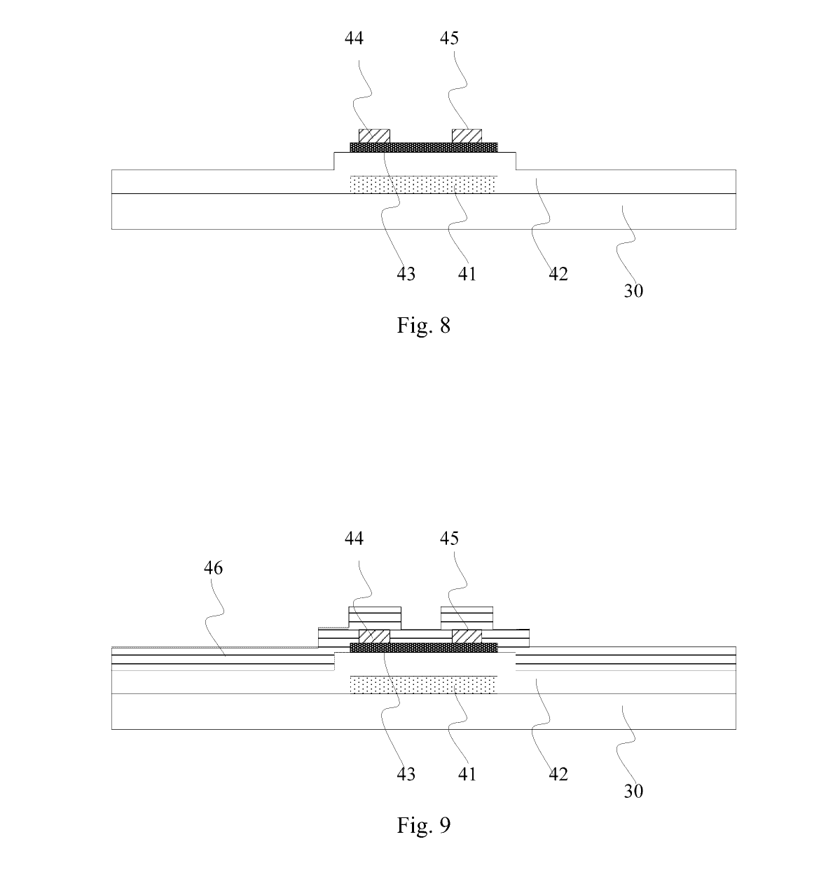

An embodiment of the present invention provides a specific method of manufacturing a display substrate, referring to FIG. 4, the specific steps comprise:

Step 401, forming, on a base substrate, a pattern of a thin film transistor. This step specifically comprises:

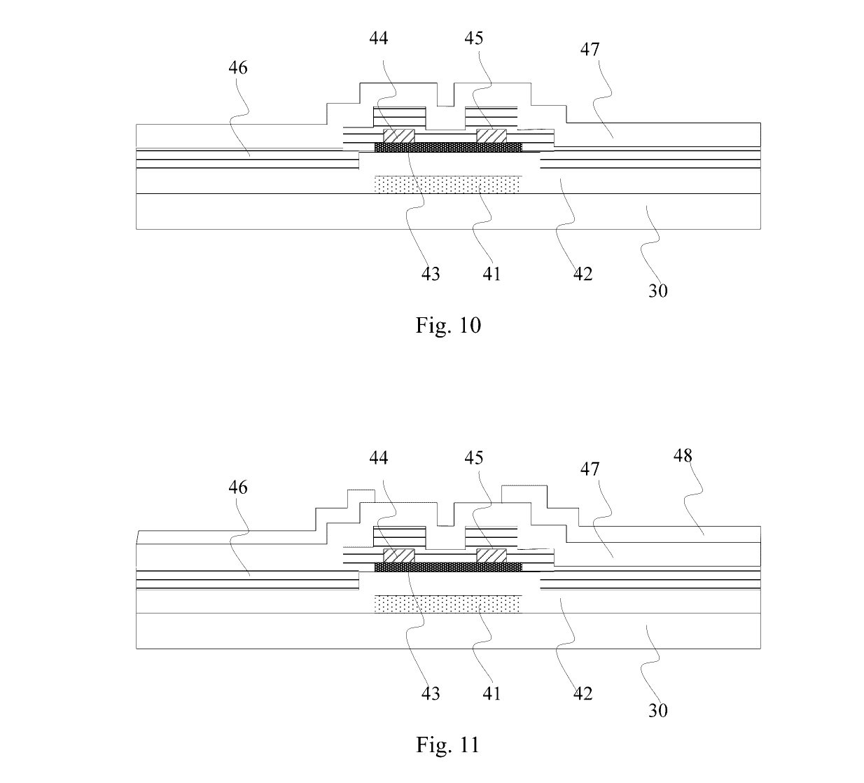

A first step, referring to FIG. 5, depositing a layer of metal thin film on the base substrate, then processing it through a composition process to form a pattern of a gate 41 and a gate line (not shown in the figure), the materials for forming the metal thin film can be non-transparent metals such as Cr, W, Ti, Ta, Mo, Al, Cu and alloy thereof.

A second step, referring to FIG. 6, depositing a SiNₓ or SiOₓ layer on the substrate comprising the pattern of the gate and the gate line, to form a gate insulating layer 42, the gate insulating layer 42 being used for covering the area above the gate line and the gate 41 for insulating the gate line and the gate from other layers.

A third step, referring to FIG. 7, depositing an amorphous silicon semiconductor material, a polycrystalline silicon material or an oxide semiconductor material above the gate insulating layer 42, then forming a pattern of an active layer 43 through a composition process.

And a fourth step, referring to FIG. 8, forming a source-drain metal thin film on the substrate comprising the pattern of the active layer 43, then forming a pattern of a data line (not shown in the figure), a source 44 and a drain 45 through a composition process.

Step 402, referring to FIG. 9, forming a pattern of a color film layer 46 on the substrate comprising the pattern of the data line, the source 44 and the drain 45. The color film layer 46 comprises color film sub areas constituted by resins of three primary colors of red (R), green (G) and blue (B).

Step 403, referring to FIG. 10, depositing a SiNₓ or SiOₓ layer on the substrate comprising the pattern of the color film layer 46, to form a passivation layer 47 for protecting the thin film transistor and the color film layer from being damaged in the subsequent manufacturing process.

Step 404, referring to FIG. 11, depositing a layer of indium tin oxide transparent conductive film on the passivation layer 47 using magnetron sputtering, and forming a pattern of a pixel electrode 48 through a composition process. The pixel electrode 48 is electrically connected with the drain 45 through a via hole that penetrates the passivation layer 47 (not shown in the figure).

Step 405, referring to FIG. 12, coating a layer of non-transparent material for forming a black matrix on the substrate comprising the pattern of the pixel electrode 48, and pre-baking the layer for 100 seconds under a condition of 80˜100° C., so as to form a non-transparent material layer 31.

Step 406, coating a layer of transparent material above the non-transparent material layer 31, to form a transparent material layer 32 for manufacturing the primary and secondary column shaped spacers, and performing pre-baking for 100 seconds under a condition of 80˜100° C.

Step 407, forming a pattern of the primary and secondary column shaped spacers and the black matrix using a mask plate corresponding to the primary and secondary column shaped spacers through exposing and developing processes and processes such as removing the photoresist after development.

Forming the pattern of the primary and secondary column shaped spacers and the black matrix using a composition process may specifically comprise:

performing exposure using a mask plate comprising a fully transparent area corresponding to a pattern of the primary column shaped spacer and a semi-transparent area corresponding to a pattern of the secondary column shaped spacer so as to cure transparent material and non-transparent material of areas corresponding to the pattern of the primary and secondary column shaped spacers; removing uncured transparent material and non-transparent material using developer, so as to form a pattern of the primary and secondary column shaped spacers and the black matrix; or

performing exposure using a mask plate comprising a first aperture corresponding to a pattern of the primary column shaped spacer and a second aperture corresponding to a pattern of the secondary column shaped spacer so as to cure transparent material and non-transparent material of areas corresponding to the pattern of the primary and secondary column shaped spacers; removing uncured transparent material and non-transparent material using developer, so as to form a pattern of the primary and secondary column shaped spacers and the black matrix.

In the process of exposure, when the exposure is performed using a mask plate comprising a fully transparent area corresponding to a pattern of the primary column shaped spacer and a semi-transparent area corresponding to a pattern of the secondary column shaped spacer, the light intensity passing through the fully transparent area is greater than the light intensity passing through the semi-transparent area. The curing speed of the transparent material layer corresponding to the fully transparent area is high, while the curing speed of the transparent material layer corresponding to the semi-transparent area is relatively low. Therefore, the height of the spacer corresponding to the fully transparent area is greater than the height of the spacer corresponding to the semi-transparent area.

Similarly, when exposure is performed using a mask plate comprising a first aperture corresponding to a pattern of the primary column shaped spacer and a second aperture corresponding to a pattern of the secondary column shaped spacer, compared with the light beam that passes through the first aperture, the light beam that passes through the second aperture will generate obvious diffraction phenomenon, such that the intensity of the light beam that passes through the second aperture is reduced. Therefore, the curing speed of the transparent material corresponding to the first aperture is high, while the curing speed of the transparent material corresponding to the second aperture is relatively low. The height of the spacer corresponding to the first aperture is greater than the height of the spacer corresponding to the second aperture.

Optionally, forming a pattern of the primary and secondary column shaped spacers and the black matrix using a composition process comprises:

forming a pattern of the primary and secondary column shaped spacers and the black matrix using a one-time composition process.

The primary and secondary column shaped spacers are both formed above the black matrix using a one-time composition process, which simplifies the manufacturing process and reduces the production cost.

Based on the same inventive concept, an embodiment of the present invention further provides a display substrate manufactured using the above method. Referring to FIG. 3c, the display substrate comprises: a base substrate 30, a black matrix 35 located above the base substrate 30, column shaped spacers formed at a side of the black matrix 35 away from the base substrate 30, the column shaped spacers comprising a transparent primary column shaped spacer 33 and a transparent secondary column shaped spacer 34.

In the display substrate provided by the embodiment of the present invention, since the primary column shaped spacer and the secondary column shaped spacer are formed with a transparent material, the black matrix can be made of a material with a relatively large OD value, thus the problem that the column shaped spacer is too high due to a relatively low OD value thereby influencing the panel display quality can be avoided.

Further, optionally, a segment difference between the primary column shaped spacer 33 and the secondary column shaped spacer 34 is 0.3˜0.7 μm.

The segment difference between the primary and secondary column shaped spacers formed through this method is 0.3˜0.7 μm. If the segment difference is in this range, it can not only play protection function to the display panel so as to prevent the display panel from being deformed due to extrusion, but also be benefit for improving the panel display quality.

Further, the black matrix 35 is made of a non-transparent material, the primary column shaped spacer 33 and the secondary column shaped spacer 34 are made of a transparent material.

The black matrix is formed using a non-transparent material, the black matrix formed has the function of preventing light crosstalk, and improving the display quality of the panel. When the primary and secondary column shaped spacers are formed using the transparent material, the black matrix can be made of a material with a relatively large OD value, thus the problem that the column shaped spacer is too high due to a relatively low OD value thereby influencing the panel display quality can be avoided.

An embodiment of the present invention further provides a display substrate, which differs from the abovementioned display substrate in that, referring to FIG. 12, the display substrate further comprises: a thin film transistor located above the base substrate 30; a color film layer 46 located above the layer where the thin film transistor locates; a pixel electrode 48 located above the color film layer 46. Moreover, the black matrix is located above the pixel electrode, the primary and secondary column shaped spacers are located above the black matrix.

Forming the color film layer on the display panel where the thin film transistor locates using the COA technology can avoid cell alignment error produced in the cell alignment process and is benefit for improving the display quality of the panel.

The display substrate may further comprise a passivation layer 47 arranged between the color film layer 46 and the pixel electrode 48, for protecting the thin film transistor and the color film layer from being damaged.

A passivation layer is arranged between the color film layer and the pixel electrode, the passivation layer can protect the color film layer and the thin film transistor from being damaged in the subsequent process effectively.

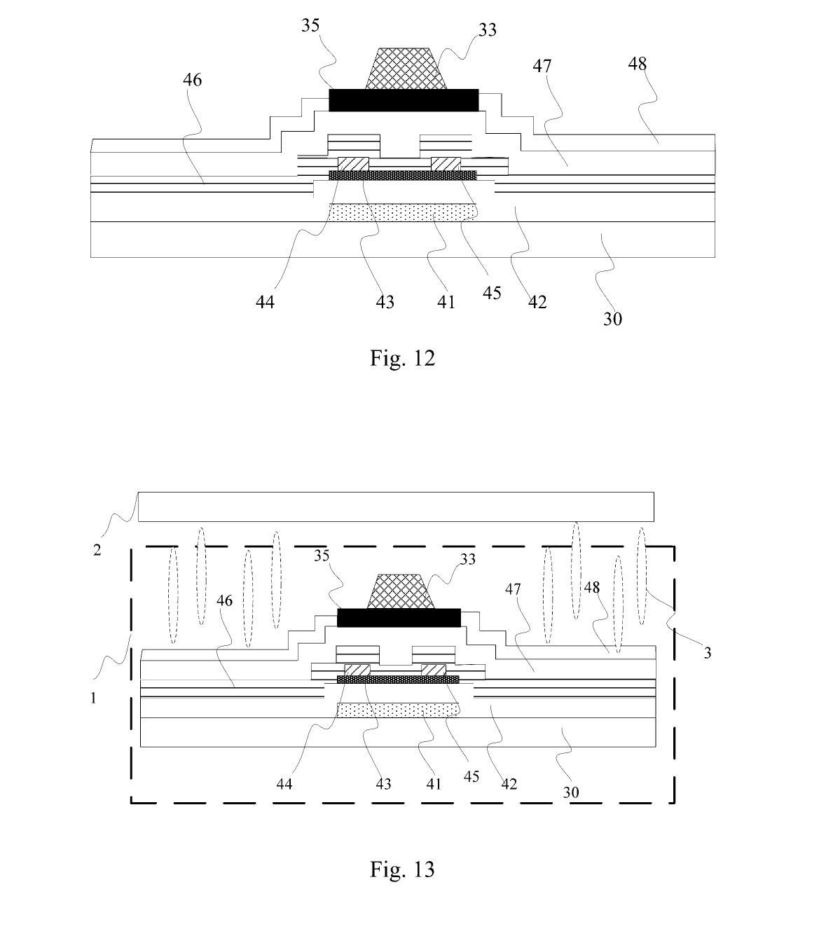

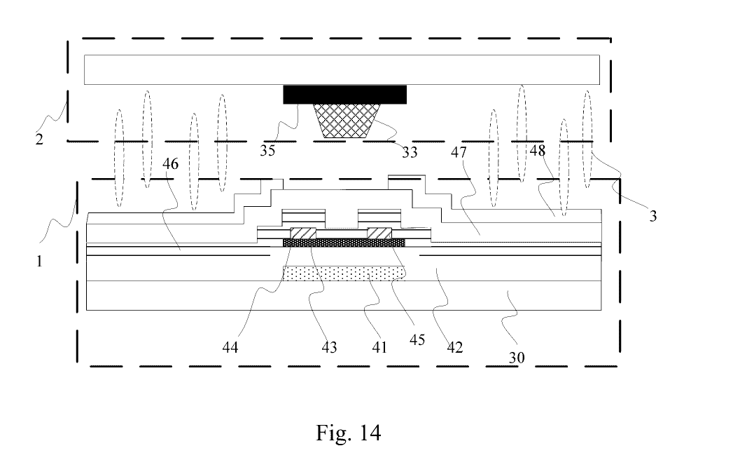

Based on the same inventive concept, an embodiment of the present invention further provides a display device, the display device comprising the above display substrate 1, an opposite substrate 2, and a liquid crystal layer 3 located between the display substrate and the opposite substrate, as shown in FIG. 13 and FIG. 14.

To sum up, embodiments of the present invention provide a display substrate, a manufacturing method thereof and a display device; in the method of manufacturing a display substrate, a non-transparent material layer for manufacturing a black matrix is formed on a base substrate firstly, then a transparent material layer for manufacturing primary and secondary column shaped spacers is formed; finally the black matrix and the primary and secondary column shaped spacers are formed through a composition process; that is, in the embodiment of the present invention, the manufacturing of the black matrix and the primary and secondary column shaped spacers can be accomplished only through two coating processes and one etching process, which simplifies the manufacturing process and reduces the production cost; moreover, since the manufacturing material of the primary and secondary column shaped spacers is a transparent material, the black matrix can be made of a material with a relatively large OD value, thus the problem that the column shaped spacer is too high due to a relatively low OD value thereby influencing the panel display quality can be avoided.

Those skilled person in the art can make various modifications and variations to the present invention without departing from the spirit and the scope of the present invention. In this way, provided that these modifications and variation of the present invention belong to the scopes of the claims of the present invention and the equivalent technologies thereof, the present invention will also intend to cover these modifications and variations.

1. A method of manufacturing a display substrate, comprising:
forming, on a base substrate, a non-transparent material layer for manufacturing a black matrix;
forming, on the substrate where the above step is performed, a transparent material layer for manufacturing primary and secondary column shaped spacers; and
forming a pattern of the primary and secondary column shaped spacers and the black matrix using a composition process.

2. The method of claim 1, wherein a segment difference between the formed primary and secondary column shaped spacers is 0.3˜0.7 μm.

3. The method of claim 1, wherein forming a pattern of the primary and secondary column shaped spacers and the black matrix using a composition process comprises:
forming a pattern of the primary and secondary column shaped spacers and the black matrix by exposing and developing photoresist using a mask plate corresponding to the pattern of the primary and secondary column shaped spacers.

4. The method of claim 3, wherein the mask plate comprises a fully transparent area corresponding to the primary column shaped spacer and a semi-transparent area corresponding to the secondary column shaped spacer; or
the mask plate comprises a first aperture corresponding to the primary column shaped spacer and a second aperture corresponding to the secondary column shaped spacer; wherein a diameter of the first aperture is greater than a diameter of the second aperture.

5. The method of claim 4, wherein forming a pattern of the primary and secondary column shaped spacers and the black matrix using a composition process comprises:
performing exposure using a mask plate comprising a fully transparent area corresponding to a pattern of the primary column shaped spacer and a semi-transparent area corresponding to a pattern of the secondary column shaped spacer so as to cure transparent material and non-transparent material of areas corresponding to the pattern of the primary and secondary column shaped spacers; removing uncured transparent material and non-transparent material using developer, so as to form a pattern of the primary and secondary column shaped spacers and the black matrix; or
performing exposure using a mask plate comprising a first aperture corresponding to a pattern of the primary column shaped spacer and a second aperture corresponding to a pattern of the secondary column shaped spacer so as to cure transparent material and non-transparent material of areas corresponding to the pattern of the primary and secondary column shaped spacers; removing uncured transparent material and non-transparent material using developer, so as to form a pattern of the primary and secondary column shaped spacers and the black matrix.

6. The method of claim 3, wherein the display substrate further comprises a thin film transistor, a color film layer and a pixel electrode;
prior to forming a non-transparent material layer for manufacturing a black matrix, the method further comprises:
forming, on the base substrate, a pattern of the thin film transistor;
forming, on the substrate comprising the pattern of the thin film transistor, a pattern of the color film layer;
forming, on the substrate comprising the pattern of the color film layer, a pattern of the pixel electrode.

7. The method of claim 6, wherein prior to forming a pattern of a pixel electrode, the method further comprises:
forming, on the substrate comprising the pattern of the color film layer, a passivation layer for protecting the thin film transistor and the color film layer from being damaged.

8. The method of claim 1, wherein forming a pattern of the primary and secondary column shaped spacers and the black matrix using a composition process comprises:
forming a pattern of the primary and secondary column shaped spacers and the black matrix using a one-time composition process.

9. A display substrate manufactured using the method of claim 1, the display substrate comprising:
a base substrate;
a black matrix located on the base substrate;
column shaped spacers formed at a side of the black matrix away from the base substrate, the column shaped spacers comprising a transparent primary column shaped spacer and a transparent secondary to column shaped spacer.

10. The display substrate of claim 9, wherein a segment difference between the formed primary and secondary column shaped spacers is 0.3˜0.7 μm.

11. The display substrate of claim 9, wherein the black matrix is made of a non-transparent material, the primary and secondary column shaped spacers are made of a transparent material.

12. The display substrate of claim 9, wherein the display substrate further comprises: a thin film transistor located above the base substrate; a color film layer located above the layer where the thin film transistor locates; a pixel electrode located above the color film layer.

13. The display substrate of claim 12, wherein the display substrate further comprises a passivation layer arranged between the color film layer and the pixel electrode, for protecting the thin film transistor and the color film layer from being damaged.

14. A display device, the display device comprising a display substrate as claimed in claim 9.

15. The display device of claim 14, wherein a segment difference between the formed primary and secondary column shaped spacers is 0.3˜0.7 μm.

16. The display device of claim 14, wherein the black matrix is made of a non-transparent material, the primary and secondary column shaped spacers are made of a transparent material.

17. The display device of claim 14, wherein the display substrate further comprises: a thin film transistor located above the base substrate; a color film layer located above the layer where the thin film transistor locates; a pixel electrode located above the color film layer.

18. The display device of claim 17, wherein the display substrate further comprises a passivation layer arranged between the color film layer and the pixel electrode, for protecting the thin film transistor and the color film layer from being damaged.
